(19) United States
(12) Patent Application Publication
(10) Pub. No.: US 2024/0153837 A1
(43) Pub. Date: May 9, 2024

(54) BARRIER ENABLED CUF AND MOLD PROCESS FOR MULTI-CHIP PACKAGING

(71) Applicant: Intel Corporation, Santa Clara, CA (US)

(72) Inventors: Ziyin LIN, Chandler, AZ (US); Vipul MEHTA, Chandler, AZ (US); Jonas CROISSANT, Hillsboro, OR (US); Jigneshkumar PATEL, Chandler, AZ (US); Dingying XU, Chandler, AZ (US); Gang DUAN, Chandler, AZ (US); Aditya Sumanth YERRAMILLI, Hillsboro, OR (US); Suriyakala RAMALINGAM, Portland, OR (US); Xavier BRUN, Chandler, AZ (US)

(21) Appl. No.: 17/983,226

(22) Filed: Nov. 8, 2022

(51) Int. Cl. H01L 23/31; H01L 23/498; H01L 25/18

(52) U.S. Cl. CPC H01L 23/3157; H01L 23/49811; H01L 25/18; H01L 24/32; H01L 2224/32225

(57) ABSTRACT

Embodiments disclosed herein include electronic packages. In an embodiment, the electronic package comprises a die, and an array of pillars adjacent to the die. In an embodiment, the electronic package further comprises an underfill under the die, where an edge of the underfill is between an inner column of pillars in the array of pillars and an outer edge of the die, and where the edge of the underfill has a height that is less than a maximum height of the underfill.

### TECHNICAL FIELD

Embodiments of the present disclosure relate to electronic packages, and more particularly to multi-chip packages that include a barrier around a perimeter of one of the chips to confine and direct flow of a capillary underfill (CUF) material.

### BACKGROUND

In advanced electronic packaging applications multiple dies or chips can be co-packaged as a multi-die module. In some instances a first die is provided at a first level, and one or more second dies are provided at a second level above the first die. In such instances, conductive pillars (e.g., copper pillars) can be formed in order to provide electrical coupling between the second dies and a bottom surface of the multi-die module. That is, the conductive pillars may be provided laterally adjacent to the first die. This creates problems with dispensing an underfill material (e.g., a capillary underfill (CUF)) below the first die. Particularly, the underfill material is held in the array of conductive pillars instead of spreading under the first die, as intended.

In order to prevent the underfill material from segregating to the conductive pillars, the spacing between the conductive pillars and the first die may be increased in order to allow for a larger keep out zone (KOZ). However, this results in an increase in the form factor of the multi-die module, and is therefore not desirable.

### BRIEF DESCRIPTION OF THE DRAWINGS

FIG. 1A is a cross-sectional illustration of a die adjacent to an array of conductive pillars with the capillary underfill (CUF) segregating to the top of the conductive pillars.

FIG. 1B is a cross-sectional illustration of a die adjacent to an array of conductive pillars with the CUF segregating to a bottom of the conductive pillars.

FIG. 2A is a cross-sectional illustration of a die adjacent to an array of conductive pillars with a barrier layer set into the array of conductive pillars so that the CUF flows under the die, in accordance with an embodiment.

FIG. 2B is a cross-sectional illustration of a die adjacent to an array of conductive pillars with a sacrificial barrier layer that has been removed after the formation of the CUF, in accordance with an embodiment.

FIG. 3 is a plan view illustration of an electronic package with an array of conductive pillars around a die, a barrier layer set into the array of conductive pillars, and an underfill within the barrier layer, in accordance with an embodiment.

FIG. 4A is a cross-sectional illustration of an electronic package with an underfill at a bottom of a multi-die module that interfaces with a barrier layer, in accordance with an embodiment.

FIG. 4B is a cross-sectional illustration of an electronic package with an underfill at a bottom of a multi-die module that has a fillet that is shaped by a sacrificial barrier layer, in accordance with an embodiment.

FIG. 4C is a cross-sectional illustration of an electronic package with an underfill at a top of a bottom die that interfaces with a barrier layer, in accordance with an embodiment.

FIG. 4D is a cross-sectional illustration of an electronic package with an underfill at a top of a bottom die that has a fillet that is shaped by a sacrificial barrier layer, in accordance with an embodiment.

FIG. 5A is a cross-sectional illustration of a die and an adjacent array of conductive pillars with an underfill that interfaces with a barrier layer, in accordance with an embodiment.

FIG. 5B is a cross-sectional illustration of the die in FIG. 5A with the barrier layer removed, in accordance with an embodiment.

FIG. 6A is a cross-sectional illustration of a die and an adjacent array of conductive pillars with an underfill that interfaces with a barrier layer, in accordance with an embodiment.

FIG. 6B is a cross-sectional illustration of the die in FIG. 6A with the barrier layer removed, in accordance with an embodiment.

FIG. 7A is a cross-sectional illustration of a die and an adjacent array of conductive pillars with an underfill that interfaces with a barrier layer, in accordance with an embodiment.

FIG. 7B is a cross-sectional illustration of the die in FIG. 7A with the barrier layer removed, in accordance with an embodiment.

FIG. 8 is a cross-sectional illustration of an electronic system with a multi-die module that includes a CUF that interfaces with a barrier layer that is set into an array of conductive pillars, in accordance with an embodiment.

FIG. 9 is a schematic of a computing device built in accordance with an embodiment.

### EMBODIMENTS OF THE PRESENT DISCLOSURE

Described herein are multi-chip packages that include a barrier around a perimeter of one of the chips to confine and direct flow of a capillary underfill (CUF) material, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

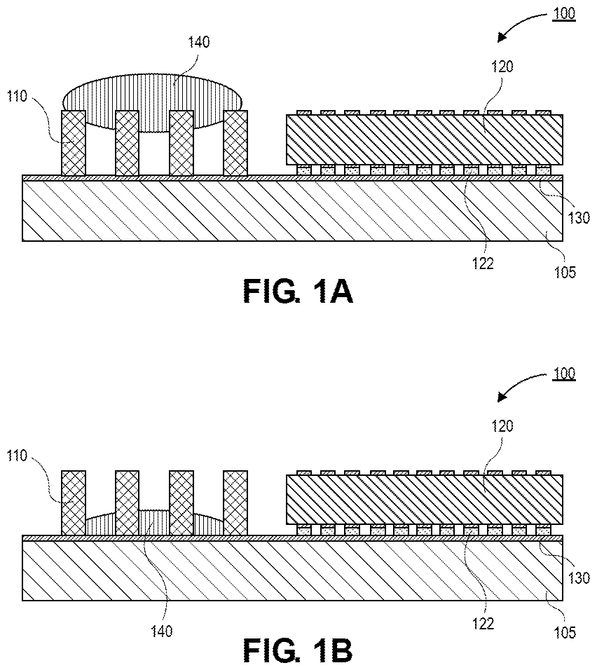

As noted above, in some multi-die or multi-chip packaging architectures an array of conductive pillars are provided adjacent to a die. Ideally, the array of conductive pillars are positioned as close to the die as possible in order to minimize the footprint of the multi-die module. However, moving the conductive pillars close to the die results in difficulty in underfilling the die. That is, the capillary underfill (CUF) material does not flow under the die and around the interconnects below the die. As such, reliability issues are present. For example, FIG. 1A illustrates one instance of an electronic package 100 where the CUF 140 does not underfill the die 120. Particularly, the CUF 140 remains at a top surface of the pillars 110 instead of extending around the interconnects 122 below the die 120. The pillars 110 and the interconnects 122 may be provided over a layer 130 and a carrier 105. The surface energy created by the pillars 110 prevents the CUF 140 from flowing to the layer 130 and around the interconnects 122. Similarly, in FIG. 1B, the CUF 140 overcomes the surface energy of the pillars 110 and reaches the layer 130. However, the CUF 140 still does not flow under the die 120. As such, the electronic package 100 has significant reliability issues.

Accordingly, embodiments disclosed herein include structures that prevent the CUF from segregating to the array of conductive pillars. Instead, capillary forces are strong enough to flow the CUF below the die and around the interconnects. In an embodiment, the structure that is used to keep the CUF from pooling in the array of conductive pillars is a barrier layer. The barrier layer may be set into the array of conductive pillars. This forces the CUF out of the conductive pillars and enables proper dispensing below the die.

In an embodiment, the CUF conforms to an edge of the barrier layer. That is, the edge of the CUF may have a profile that is distinct from the profile of a typical CUF without a barrier layer (i.e., a sloping concave fillet shape that has a first end at a top of the CUF and a substantially continuous curve to the bottom of the CUF). The height of the edge of the CUF may be less than a total height of the CUF in some embodiments. Furthermore, the profile of the CUF may be a non-vertical sidewall. In some instances, the edge of the CUF may form an undercut below the top surface of the CUF. For example, when the barrier layer is rounded the CUF may have an edge that conforms to the round surface of the barrier layer. In an embodiment, the barrier layer may be a material that is distinct from the CUF. This provides a clear interfaces that can be identified using various microscopy methods. In embodiments where the barrier layer persists to the final structure, the barrier layer must conform to reliability standards and the like.

However, if it is difficult to meet the reliability standards with the barrier layer material, then the barrier layer may be a sacrificial layer. In such embodiments, the barrier layer may first be deposited in the array of conductive pillars, and the CUF may then be dispensed. After dispensing and curing the CUF, the barrier layer may be removed (e.g., with an etching or chemical cleaning process). Despite being removed, the presence of the barrier layer can still be inferred. This is because the CUF will have a distinctive fillet shape along the edge of the CUF that interfaced with the barrier layer before the barrier layer is removed. For example, the edge of the CUF may undercut the top and/or bottom surface of the CUF in some embodiments.

Embodiments disclosed herein are flexible in order to work with several different integration process flows. For example, in a top die first process flow, the CUF may be in contact with the top die of the multi-die module. Alternatively, in a top die last process flow, the CUF may be provided at a bottom of the multi-die module around the bottom die.

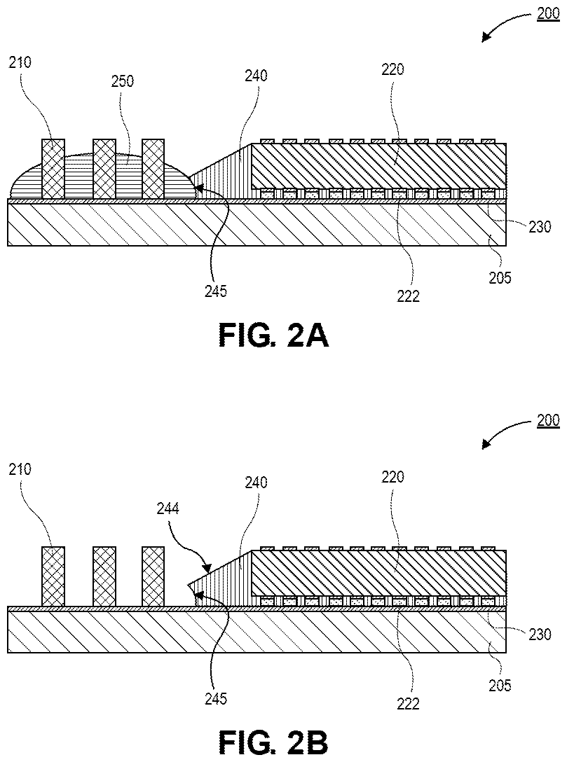

Referring now to FIG. 2A, a cross-sectional illustration of an electronic package 200 is shown, in accordance with an embodiment. The electronic package 200 may be provided on a carrier 205. The carrier 205 may be any suitable substrate used for the fabrication of the electronic package 200. The carrier 205 may be removed in subsequent processing operations. A first layer 230 may be provided over the carrier 205. The first layer 230 may be a seed layer, a metal layer, one or more redistribution layers, pad layers, or the like. In an embodiment, a first die 220 may be provided over the first layer 230. The first die 220 may be a compute die, such as a processor, a graphics processor, a system on a chip (SoC), an ASIC, or the like. The first die 220 may also be a memory die or any other type of die. The first die 220 may be a die in a multi-die module (described in greater detail below). That is, the first die 220 may be communicatively coupled to one or more other dies in some embodiments. In some instances, the first die 220 may be referred to as a chiplet.

In an embodiment, an array of conductive pillars 210 may be provided adjacent to the first die 220. The conductive pillars 210 may be copper pillars or the like. The copper pillars may be formed in order to couple a second die (not shown) to the first layer 230. While three conductive pillars 210 are shown in FIG. 2A, it is to be appreciated that any number of conductive pillars 210 may be provided adjacent to the first die 220. In an embodiment, the conductive pillars 210 may have a height that is greater than a thickness of the first die 220.

In an embodiment, a barrier layer 250 is set into the array of conductive pillars 210. As used herein, being “set into” the array of conductive pillars 210 refers to the barrier layer 250 being between at least two of the conductive pillars 210. For example, in FIG. 2A, the barrier layer 250 is between a set of three conductive pillars 210. The barrier layer 250 may also extend out into the space between an edge of the first die 220 and an inner most conductive pillar 210. In the illustrated embodiment, the barrier layer 250 has a height that is less than the height of the conductive pillars 210. However, in some embodiments, the barrier layer 250 may have a height that is substantially equal to the height of the conductive pillars 210.

In an embodiment, the CUF 240 may underfill the first die 220. That is, the CUF 240 may surround interconnects 222 that are provided between the first die 220 and the first layer 230. In an embodiment, the CUF 240 also extends laterally out from the first die 220 to the space between the first die 220 and an innermost conductive pillar 210. The CUF 240 may conform to the shape of the barrier layer 250 as well. For example, edge 245 of the CUF 240 may be a non-vertical edge. As used herein, a CUF 240 with a “non-vertical edge” may be an edge that is not substantially parallel to the edge of the die that is being underfilled by the CUF 240. In some instances, a non-vertical edge 245 may also be a non-planar edge. For example, in FIG. 2A, the edge 245 has a rounded shape. More particularly, the edge 245 may undercut one or both of a top surface and a bottom surface of the CUF 240 in some embodiments. More generally, the height of the edge 245 may be less than a maximum height of the CUF 240.

Referring now to FIG. 2B, a cross-sectional illustration of an electronic package 200 is shown, in accordance with an additional embodiment. The electronic package 200 in FIG. 2B may be substantially similar to the electronic package 200 in FIG. 2A, with the exception of the barrier layer 250. Particularly, the barrier layer 250 is removed from the electronic package 200 in FIG. 2B. That is, the barrier layer 250 may be a sacrificial barrier layer 250. For example, the sacrificial barrier layer may be formed (similar to the embodiment in FIG. 2A), and the CUF 240 may be dispensed. After the CUF 240 is dispensed and cured, the sacrificial barrier layer may be removed. The barrier layer may be removed when the barrier layer does not have material properties that conform to reliability standards or the like of the electronic package 200.

Removal of the sacrificial barrier layer does leave behind a structural feature that can be used to identify that a barrier layer was used. For example, the edge 245 has a distinctive fillet where the CUF 240 conformed to the edge of the sacrificial barrier layer. For example, in FIG. 2B, the fillet of the edge 245 has a rounded shape that undercuts the top surface 244 of the CUF 240. While a particular shape of the edge 245 is shown in FIG. 2B, it is to be appreciated that other edge 245 shapes can also be formed depending on the flow characteristics of the sacrificial barrier layer.

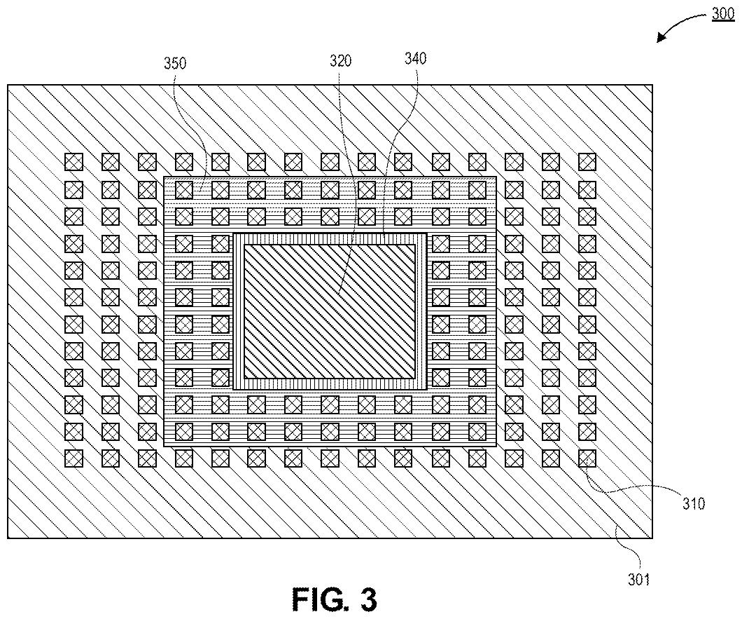

Referring now to FIG. 3, a plan view illustration of an electronic package 300 is shown, in accordance with an embodiment. In an embodiment, the electronic package 300 may include a substrate 301. A first die 320 may be provided over the package substrate 301. In an embodiment, an array of conductive pillars 310 may be provided around the first die 320. While shown as surrounding all sides of the first die 320, it is to be appreciated that the array of conductive pillars 310 may be provided adjacent to one or more of the sides of the first die 320.

In an embodiment, a barrier layer 350 may be set into the array of conductive pillars 310. For example, the barrier layer 350 may be set into the inner two most columns of conductive pillars 310 around the first die 320. That is, the barrier layer 350 does not need to cover the entirety of the array of conductive pillars 310. While three additional columns of conductive pillars 310 are shown outside of the barrier layer 350 in FIG. 3, it is to be appreciated that any number of columns of conductive pillars 310 may be provided outside of the barrier layer 350. Additionally, while two columns of conductive pillars 310 are covered by the barrier layer 350, any number of columns may be covered by the barrier layer 350. For example, there may be fifty or more columns of conductive pillars 310 adjacent to one of the sides of the first die 320, and the barrier layer 350 may cover five or more of the columns of conductive pillars 310. The barrier layer 350 may conform to the CUF 340 that is under and around the first die 320.

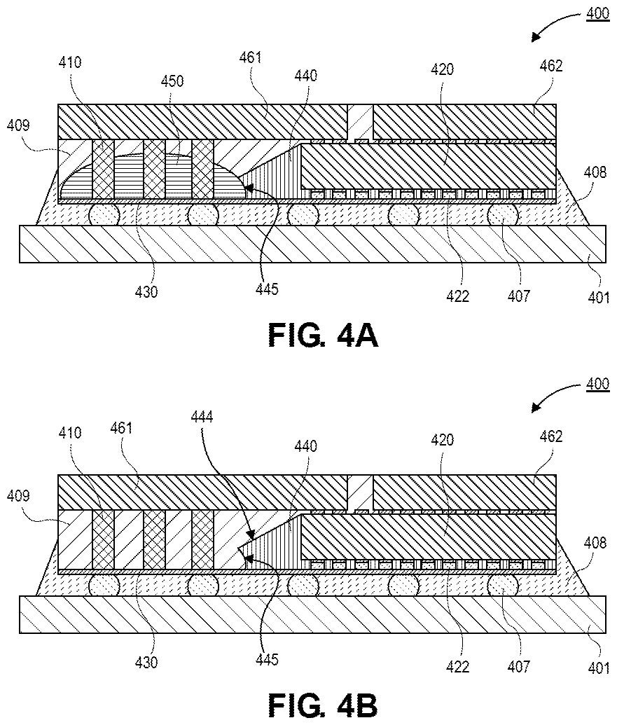

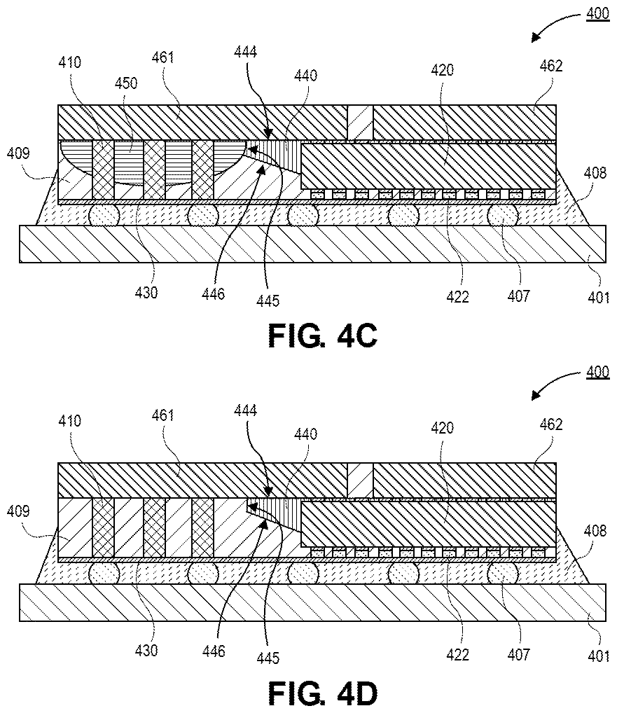

Referring now to FIG. 4A, a cross-sectional illustration of an electronic package 400 is shown, in accordance with an embodiment. In an embodiment, the electronic package 400 may comprise a package substrate 401. Interconnects 407 (e.g., solder interconnects) may couple the package substrate 401 to a first layer 430. The first layer 430 may be a seed layer, a metal layer, one or more redistribution layers, a pad layer, or the like. In an embodiment, interconnects 407 may be surrounded by an underfill 408.

In an embodiment, the electronic package 400 may be a multi-die package 400. For example, a first die 420 may be connected to the first layer 430 by interconnects 422, and second dies 461 and 462 may be provided above the first die 420. One or both of the second dies 461 and 462 may be coupled to the first die 420 by interconnects or the like. Additionally, the second die 461 may be coupled to the first layer 430 by an array of conductive pillars 410 that are adjacent to the first die 420.

In an embodiment, a barrier layer 450 may be set into the array of conductive pillars 410. The barrier layer 450 may extend out towards the first die 420. In an embodiment, a CUF 440 may interface with the barrier layer 450. The CUF 440 may also underfill the interconnects 422 between the first die 420 and the first layer 430. In an embodiment, the edge 445 of the CUF 440 may contact the barrier layer 450. For example, the edge 445 may conform to the shape of the barrier layer 450. As such, the edge 445 of the CUF 440 may be non-vertical and non-planar. In a particular embodiment, the edge 445 may undercut a top surface of the CUF 440. In an embodiment, a mold layer 409 or other underfill material may surround the conductive pillars 410 and the second dies 461 and 462.

Referring now to FIG. 4B, a cross-sectional illustration of an electronic package 400 is shown, in accordance with an additional embodiment. The electronic package 400 in FIG. 4B may be substantially similar to the electronic package 400 in FIG. 4A, with the exception of the barrier layer 450. Particularly, the barrier layer 450 is omitted from the structure of the electronic package 400 in FIG. 4B. However, it is to be appreciated that a sacrificial barrier layer may be used to form the structure shown in FIG. 4B. For example, a sacrificial barrier layer may be provided in the array of conductive pillars 410, and the CUF 440 may be dispensed. After dispensing the CUF 440, the sacrificial barrier layer may be removed. Such a process leaves behind a distinctive fillet in the edge 445 of the CUF 440. Particularly, the edge 445 may be non-vertical and non-planar. The shape of the edge 445 is dictated by the flow properties of the sacrificial barrier layer 450. In a particular embodiment, the edge 445 undercuts a top surface 444 of the CUF 440.

In the embodiments shown in FIGS. 4A and 4B, the processing may be described as a top die last process flow. That is, the first die 420 and the conductive pillars 410 are assembled first, and the CUF 440 is dispensed. Thereafter, the second dies 461 and 462 may be attached. However, in other embodiments, a top die first assembly approach may be used. In a top die first assembly, the conductive pillars 410 are attached to the second die 461, and then the first die 420 is attached to the second die 461. Examples of such top die first structures are shown in FIG. 4C and FIG. 4D.

Referring now to FIG. 4C, a cross-sectional illustration of an electronic package 400 is shown, in accordance with an embodiment. The electronic package 400 may be formed with a top die first assembly process. As such, the barrier layer 450 may be dispensed directly over the second die 461. That is, the barrier layer 450 may contact the second die 461 in some embodiments. Additionally, the CUF 440 may be provided so that it contacts the second die 461. The CUF 440 may surround the interconnects between the second dies 461/462 and the first die 420.

In an embodiment, the CUF 440 may have an edge 445 that contacts the barrier layer 450. The edge 445 may undercut the bottom surface 446 of the CUF 440. In some embodiments, the top surface of the CUF 440 may also be undercut by the edge 445. As shown, the bottom surface 446 of the CUF 440 may be separated from the first layer 430 by a portion of the mold layer 409 or additional underfill.

Referring now to FIG. 4D, a cross-sectional illustration of an electronic package 400 is shown, in accordance with an additional embodiment. In an embodiment, the electronic package 400 in FIG. 4D may be substantially similar to the electronic package 400 in FIG. 4C, with the exception of the barrier layer 450. Particularly, the barrier layer 450 is omitted from the electronic package 400 in FIG. 4D. However, since a sacrificial barrier layer is used to form the electronic package 400, the edge 445 of the CUF 440 retains the distinctive fillet shape. That is, the edge 445 may be non-vertical and non-planar in some embodiments. In some instances, the edge 445 may undercut the top surface 444 and/or the bottom surface 446 of the CUF 440.

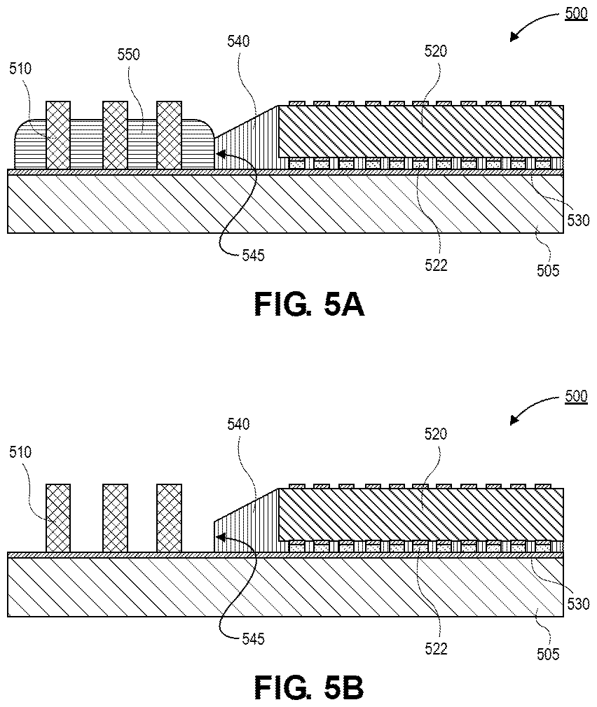

In the embodiments described in greater detail above, a distinctive fillet shape is provided for the edge of the CUF. However, it is to be appreciated that the fillet shape is not limited to any particular shape. The shape of the edge of the CUF may be dictated by the shape of the barrier layer (or sacrificial barrier layer). The barrier layer (or sacrificial barrier layer) may have shapes that are dictated, at least in part, by the flow characteristics of the material dispensed for use as the barrier layer. Examples of other edge fillet shapes are shown in FIGS. 5A-7B. Though, it is to be appreciated that embodiments are not limited to the specific examples illustrated in the Figures. Additionally, while depicted with a top die last flow, similar structures may be formed with a top die first process flow, as those skilled in the art will recognize.

Referring now to FIG. 5A, a cross-sectional illustration of an electronic package 500 at a stage of manufacture is shown, in accordance with an embodiment. In an embodiment, the electronic package 500 is being assembled over a carrier 505. A first layer 530 may be provided over the carrier 505. A first die 520 may be provided over the first layer 530. Interconnects 522 may couple the first die 520 to the first layer 530 in some embodiments. As shown, an array of conductive pillars 510 are provided adjacent to the first die 520. In an embodiment, a barrier layer 550 may be set into the array of conductive pillars 510. In an embodiment, the barrier layer 550 has a substantially flat top surface with rounded corners. The sidewalls of the barrier layer 550 may be substantially vertical in some instances. Accordingly, the CUF 540 may have an edge 545 that has a substantially vertical surface. The top surface of the CUF 540 may be non-horizontal in some instances. That is, an end of the CUF 540 away from the first die 520 may be shorter than an end of the CUF 540 at the edge of the first die 520.

Referring now to FIG. 5B, a cross-sectional illustration of an electronic package 500 at a stage of manufacture is shown, in accordance with an additional embodiment. In an embodiment, the electronic package 500 in FIG. 5B may be substantially similar to the electronic package 500 in FIG. 5A, with the exception of the barrier layer 550. More particularly, the barrier layer 550 is omitted in the embodiment shown in FIG. 5B. However, the edge 545 of the CUF 540 may still have a shape that demonstrates the previous presence of a sacrificial barrier layer. For example, the edge 545 may be substantially vertical, similar to the edge 545 shown in FIG. 5A.

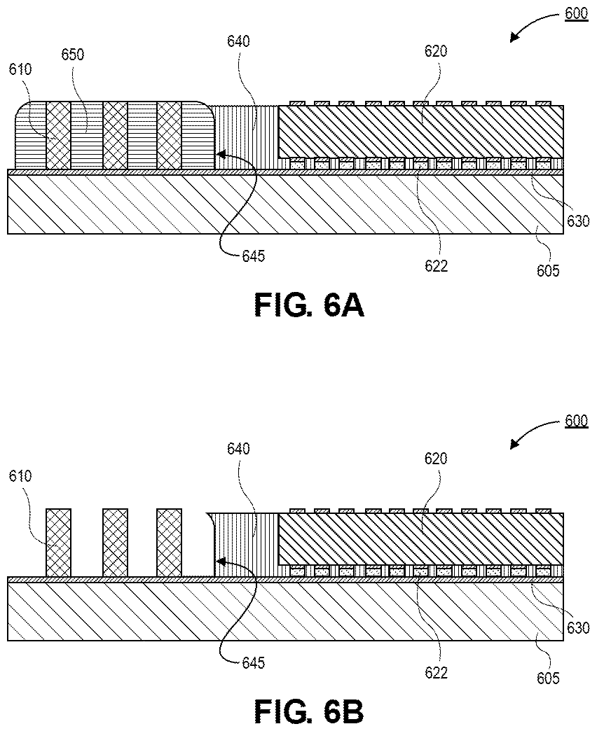

Referring now to FIG. 6A a cross-sectional illustration of an electronic package 600 at a stage of manufacture is shown, in accordance with an embodiment. In an embodiment, the electronic package 600 is being assembled over a carrier 605. A first layer 630 may be provided over the carrier 605. A first die 620 may be provided over the first layer 630. Interconnects 622 may couple the first die 620 to the first layer 630 in some embodiments. As shown, an array of conductive pillars 610 are provided adjacent to the first die 620. In an embodiment, a barrier layer 650 may be set into the array of conductive pillars 610. In an embodiment, the barrier layer 650 has a substantially flat top surface with rounded corners. The height of the barrier layer 650 may be substantially similar to the height of the conductive pillars 610. The sidewalls of the barrier layer 650 may be substantially vertical in some instances.

In an embodiment, the CUF 640 may be deposited to a thickness that is substantially equal to the height of the barrier layer 650. Accordingly, the CUF 640 may have an edge 645 that has a substantially vertical portion and a curved portion that wraps around the corner of the barrier layer 650. The top surface of the CUF 640 may be horizontal in some instances.

Referring now to FIG. 6B, a cross-sectional illustration of an electronic package 600 at a stage of manufacture is shown, in accordance with an additional embodiment. In an embodiment, the electronic package 600 in FIG. 6B may be substantially similar to the electronic package 600 in FIG. 6A, with the exception of the barrier layer 650. More particularly, the barrier layer 650 is omitted in the embodiment shown in FIG. 6B. However, the edge 645 of the CUF 640 may still have a shape that demonstrates the previous presence of a sacrificial barrier layer. For example, the edge 645 may have a vertical portion and a curved portion.

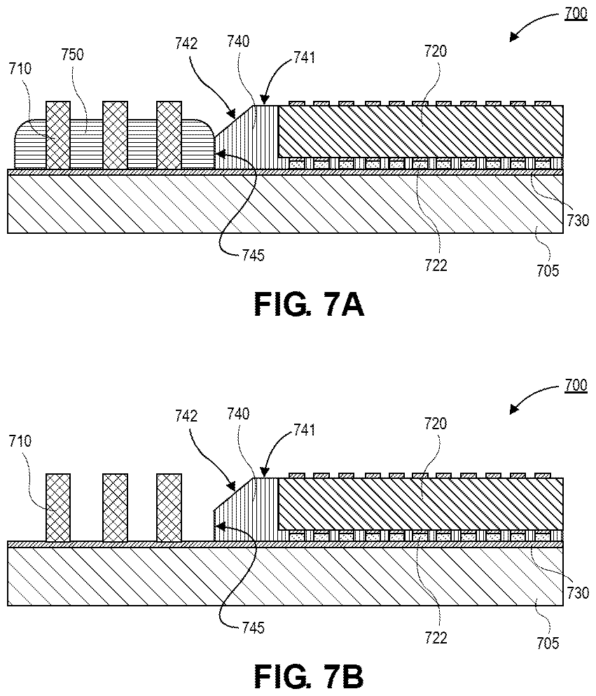

Referring now to FIG. 7A, a cross-sectional illustration of an electronic package 700 at a stage of manufacture is shown, in accordance with an embodiment. In an embodiment, the electronic package 700 is being assembled over a carrier 705. A first layer 730 may be provided over the carrier 705. A first die 720 may be provided over the first layer 730. Interconnects 722 may couple the first die 720 to the first layer 730 in some embodiments. As shown, an array of conductive pillars 710 are provided adjacent to the first die 720. In an embodiment, a barrier layer 750 may be set into the array of conductive pillars 710. In an embodiment, the barrier layer 750 has a substantially flat top surface with rounded corners. The sidewalls of the barrier layer 750 may be substantially vertical in some instances. Accordingly, the CUF 740 may have an edge 745 that has a substantially vertical surface. The top surface of the CUF 740 may have a horizontal portion 741 and a non-horizontal portion 742 in some instances. That is, an end of the CUF 740 away from the first die 720 may be shorter than an end of the CUF 740 at the edge of the first die 720.

Referring now to FIG. 7B, a cross-sectional illustration of an electronic package 700 at a stage of manufacture is shown, in accordance with an additional embodiment. In an embodiment, the electronic package 700 in FIG. 7B may be substantially similar to the electronic package 700 in FIG. 7A, with the exception of the barrier layer 750. More particularly, the barrier layer 750 is omitted in the embodiment shown in FIG. 7B. However, the edge 745 of the CUF 740 may still have a shape that demonstrates the previous presence of a sacrificial barrier layer. For example, the edge 745 may be a vertical surface in some embodiments.

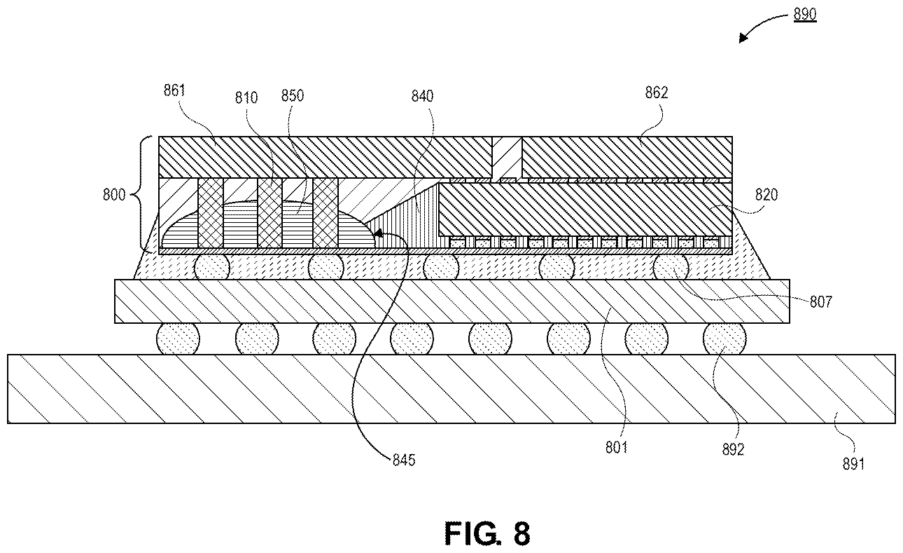

Referring now to FIG. 8, a cross-sectional illustration of an electronic system 890 is shown, in accordance with an embodiment. In an embodiment, the electronic system 890 may comprise a board 891, such as a printed circuit board (PCB). In an embodiment, the board 891 may be coupled to a package substrate 801 by interconnects 892, such as solder interconnects 892. Though, other interconnect architectures may also be used in various embodiments. In an embodiment, the package substrate 801 is coupled to a multi-chip module 800 by interconnects 807.

The multi-chip module 800 may comprise a first die 820 in a first layer and second dies 861 and 862 in a second layer. An array of conductive pillars 810 may couple the second die 861 to the bottom of the multi-chip module 800. In an embodiment, a barrier layer 850 may be set into the array of conductive pillars 810. Additionally, a CUF 840 may interface with the barrier layer 850. That is, an edge 845 of the CUF 840 may conform to a shape of the barrier layer 850. For example, the edge 845 may be non-vertical, non-planar, and undercut the top surface of the CUF 840.

In the illustrated embodiment, the barrier layer 850 persists into the final structure. In other embodiments, the barrier layer 850 may be omitted. However, the distinctive fillet shape of the edge 845 of the CUF 840 may remain, since a sacrificial barrier layer may be used to control the flow of the CUF 840. Additionally, while shown in a top die last process flow configuration, similar embodiments may be formed with a top die first process flow configuration. More generally, any of the electronic package architectures described in greater detail herein may be integrated into the electronic system 890.

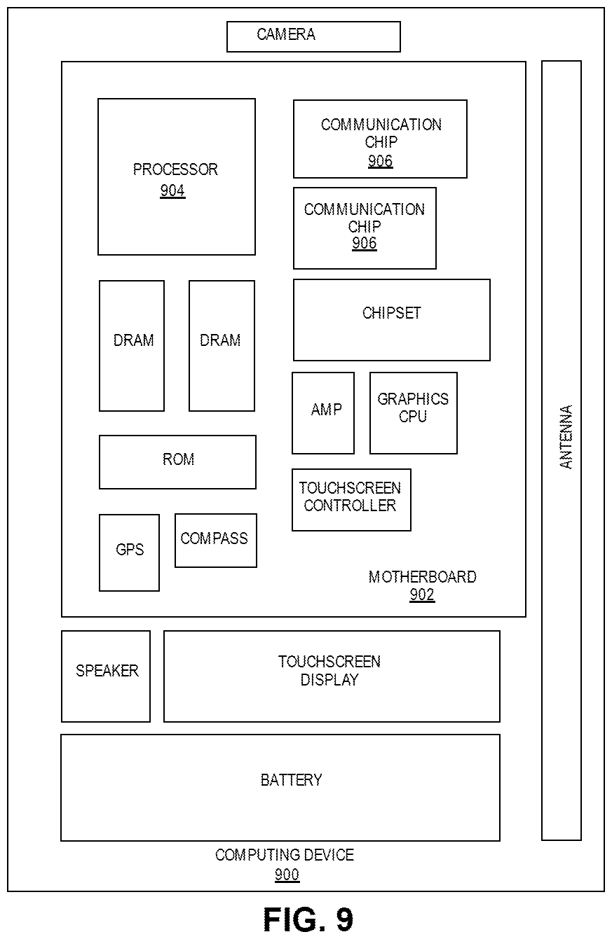

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic system that includes a multi-chip module with an underfill that includes a non-vertical fillet edge that interfaces with a barrier layer or previously interfaced with a sacrificial barrier layer, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic system that includes a multi-chip module with an underfill that includes a non-vertical fillet edge that interfaces with a barrier layer or previously interfaced with a sacrificial barrier layer, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a die; an array of pillars adjacent to the die; and an underfill under the die, wherein an edge of the underfill is between an inner column of pillars in the array of pillars and an outer edge of the die, and wherein the edge of the underfill has a height that is less than a maximum height of the underfill.

Example 2: the electronic package of Example 1, wherein the edge of the underfill has a height that is less than a height of the array of pillars.

Example 3: the electronic package of Example 1 or Example 2, wherein the edge of the underfill undercuts a top surface of the underfill.

Example 4: the electronic package of Examples 1-3, further comprising: a barrier provided in the array of pillars, wherein the underfill contacts the barrier.

Example 5: the electronic package of Example 4, wherein the barrier is a different material than the underfill.

Example 6: the electronic package of Example 4, wherein the barrier extends up to five columns deep into the array of pillars.

Example 7: the electronic package of Example 4, wherein the barrier has a height that is shorter than a height of the pillars in the array of pillars.

Example 8: the electronic package of Examples 1-7, further comprising: a board, wherein the electronic package is coupled to the board, and wherein the board and the electronic package are part of a computing system.

Example 9: an electronic package, comprising: a package substrate; a first die on the package substrate; an array of pillars adjacent to the first die; a second die over the pillars and the first die; and an underfill between the first die and the array of pillars, wherein the underfill has a non-vertical sidewall, and wherein the sidewall has a height that is less than a maximum height of the underfill.

Example 10: the electronic package of Example 9, wherein the underfill is at a bottom of the first die.

Example 11: the electronic package of Example 9 or Example 10, wherein the underfill is at a top of the first die, and wherein the underfill contacts the second die.

Example 12: the electronic package of Examples 9-11, wherein the non-vertical sidewall undercuts a bottom surface and/or a top surface of the underfill.

Example 13: the electronic package of Examples 9-12, further comprising a barrier layer in the array of pillars.

Example 14: the electronic package of Example 13, wherein the barrier layer contacts the non-vertical sidewall of the underfill.

Example 15: the electronic package of Example 13, wherein the barrier layer extends up to five columns into the array of pillars.

Example 16: the electronic package of Examples 13-15, wherein the barrier layer is a different material than the underfill.

Example 17: the electronic package of Examples 13-16, wherein the barrier layer contacts the second die.

Example 18: the electronic package of Examples 13-17, wherein the barrier layer is spaced away from the second die.

Example 19: an electronic package, comprising: a die; an array of pillars adjacent to the die; a barrier layer set into the array of pillars; and an underfill between the die and the barrier layer, wherein the underfill conforms to the shape of the barrier layer.

Example 20: the electronic package of Example 19, wherein a sidewall of the underfill undercuts a top surface of the underfill.

Example 21: the electronic package of Example 19 or Example 20, wherein the barrier layer is a different material than the underfill.

Example 22: the electronic package of Examples 19-21, wherein the barrier layer extends up to five columns deep into the array of pillars.

Example 23: an electronic system, comprising: a board; a package substrate coupled to the board; and a multi-die module coupled to the package substrate, wherein the multi-die module comprises: a first die; an array of columns adjacent to the first die; a second die over the first die; and an underfill, wherein an edge of the underfill is provided between the first die and the array of columns, and wherein the edge of the underfill is non-vertical and wherein the edge of the underfill has a height that is less than a maximum height of the underfill.

Example 24: the electronic system of Example 23, wherein the edge of the underfill undercuts a top surface and/or a bottom surface of the underfill.

Example 25: the electronic system of Example 23 or Example 24, wherein the underfill contacts the second die.

What is claimed is:

1. An electronic package, comprising:
a die;
an array of pillars adjacent to the die; and
an underfill under the die, wherein an edge of the underfill is between an inner column of pillars in the array of pillars and an outer edge of the die, and wherein the edge of the underfill has a height that is less than a maximum height of the underfill.

2. The electronic package of claim 1, wherein the edge of the underfill has a height that is less than a height of the array of pillars.

3. The electronic package of claim 1, wherein the edge of the underfill undercuts a top surface of the underfill.

4. The electronic package of claim 1, further comprising:
a barrier provided in the array of pillars, wherein the underfill contacts the barrier.

5. The electronic package of claim 4, wherein the barrier is a different material than the underfill.

6. The electronic package of claim 4, wherein the barrier extends up to five columns deep into the array of pillars.

7. The electronic package of claim 4, wherein the barrier has a height that is shorter than a height of the pillars in the array of pillars.

8. The electronic package of claim 1, further comprising:
a board, wherein the electronic package is coupled to the board, and wherein the board and the electronic package are part of a computing system.

9. An electronic package, comprising:
a package substrate;
a first die on the package substrate;
an array of pillars adjacent to the first die;
a second die over the pillars and the first die; and
an underfill between the first die and the array of pillars, wherein the underfill has a non-vertical sidewall, and wherein the sidewall has a height that is less than a maximum height of the underfill.

10. The electronic package of claim 9, wherein the underfill is at a bottom of the first die.

11. The electronic package of claim 9, wherein the underfill is at a top of the first die, and wherein the underfill contacts the second die.

12. The electronic package of claim 9, wherein the non-vertical sidewall undercuts a bottom surface and/or a top surface of the underfill.

13. The electronic package of claim 9, further comprising a barrier layer in the array of pillars.

14. The electronic package of claim 13, wherein the barrier layer contacts the non-vertical sidewall of the underfill.

15. The electronic package of claim 13, wherein the barrier layer extends up to five columns into the array of pillars.

16. The electronic package of claim 13, wherein the barrier layer is a different material than the underfill.

17. The electronic package of claim 13, wherein the barrier layer contacts the second die.

18. The electronic package of claim 13, wherein the barrier layer is spaced away from the second die.

19. An electronic package, comprising:
a die;
an array of pillars adjacent to the die;
a barrier layer set into the array of pillars; and
an underfill between the die and the barrier layer, wherein the underfill conforms to the shape of the barrier layer.

20. The electronic package of claim 19, wherein a sidewall of the underfill undercuts a top surface of the underfill.

21. The electronic package of claim 19, wherein the barrier layer is a different material than the underfill.

22. The electronic package of claim 19, wherein the barrier layer extends up to five columns deep into the array of pillars.

23. An electronic system, comprising:
a board;
a package substrate coupled to the board; and
a multi-die module coupled to the package substrate, wherein the multi-die module comprises:
a first die;
an array of columns adjacent to the first die;
a second die over the first die; and
an underfill, wherein an edge of the underfill is provided between the first die and the array of columns, and wherein the edge of the underfill is non-vertical and wherein the edge of the underfill has a height that is less than a maximum height of the underfill.

24. The electronic system of claim 23, wherein the edge of the underfill undercuts a top surface and/or a bottom surface of the underfill.

25. The electronic system of claim 23, wherein the underfill contacts the second die.
